(19) United States
(12) Patent Application Publication
(10) Pub. No.: US 2009/0150102 A1
(43) Pub. Date: Jun. 11, 2009

(54) Spectral Analysis with adaptive resolution

(76) Inventor: Andrey Khilko, Redwood City, CA (US)

Correspondence Address: Bo-In Lin, 13445 Mandoli Drive, Los Altos Hills, CA, 94022, US

(21) Appl. No.: 12/315,697

(22) Filed: Dec. 5, 2008

Related U.S. Application Data
(60) Provisional application No. 61/005,632, filed on Dec. 5, 2007.

(51) Int. Cl. G01R 23/16

(52) U.S. Cl. 702/77

(57) ABSTRACT

The present invention discloses a method of spectral analysis, backward compatible (both methodically and computationally) with traditional Fourier-based techniques, but free from limitation of static time-frequency resolution, which is often a cause of measurement inaccuracy. It is disclosed a techniques to combine convenience of Fourier-based techniques with advantages of MRA.

This Non-provisional application claims a Priority Date of Dec. 5, 2007 benefited from a Provisional Patent Applications 61/005,632 filed by an Applicant as one of the Inventors of this application. The disclosures made in Patent Application 61/005,632 are hereby incorporated by reference in this application.

### BACKGROUND OF THE INVENTION

1. Field of the Invention

This invention relates generally to data analysis. More particularly, this invention relates to spectral analysis based on Fourier Transform (FT).

2. Description of the Prior Art

Measurement of spectral characteristics of data has a fundamental trade-off often referred to as Uncertainty Principle: attempt to increase resolution in frequency domain lowers resolution in time domain and vice versa. In existing Fourier-based methods, resolution is static: decision about the time-frequency resolution trade-off must be made a priori and cannot be changed in the middle of the measurement based on actual characteristics of the measured data. If the data has real time nature and its properties are not known in advance then existing Fourier-based analysis cannot generally provide accurate information about both, presence of a particular frequency in the data spectrum and time interval during which the frequency is present. Accuracy of such analysis (when the time-frequency resolution cannot be pre-configured optimally for measured data) will be lower than the fundamental limit implied by the Uncertainty Principle. Same problem exists when data contains concurrent spectral components with different uncertainties that cannot be analyzed jointly when resolution is static.

Even though the time-frequency resolution trade-off is the most common manifestation of the Uncertainty Principle it can also manifest itself as spatial resolution vs. frequency resolution. In some applications, (i.e. radar data analysis) these resolutions directly relate to each other, because the delay of reflected signal is determined by distance to reflector. However, in applications such as image processing, timing characteristics may be not applicable at all. For clarity reasons, only the time-frequency resolution is mentioned below in this document. For those skilled in the art it is clear that either manifestation may arise depending on the nature of considered application.

A number of alternatives have been proposed to deal with the problem of static resolution of Fourier-based analysis. The most successful one is Multiresolution Analysis (MRA) based on Continuous Wavelet Transform (CWT) or Discrete Wavelet Transform (DWT). (See for example “A Wavelet Tour of Signal Processing” by S. G. Mallat, Academic Press, 1999.) However, the CWT is computationally expensive and operates different terminology whereas the DWT provides nonlinear frequency grid and the resolution of the DWT process is not easily scalable from practical prospective. Therefore in most cases, these alternatives cannot be immediately used as direct replacements of Fourier-based techniques and require new analysis methodology.

Some examples of the techniques apply the wavelet-based methods. These methods were introduced instead of using the classical Fourier methods due to poor time localization and lack of MRA ability of the latter:

U.S. Pat. No. 6,097,669 to Jordan et al. describes method of real time filtering of sodar signals using wavelets, since “ . . . unlike Fourier transforms, wavelets can resolve isolated features in a time series (or range for sodar signals).”

U.S. Pat. No. 6,292,592 to Chen et al.: method of processing radar and electro-optic image data using DWT rather than Fourier because “ . . . the basis functions for the DWT are much more general and are localized in both frequency and time.”

U.S. Pat. No. 5,561,431 to Peele et al. describes method of classification of sensor data based on wavelet transform due to its ability to provide time localization and MRA.

U.S. Pat. No. 6,727,725 to Devaney and Eren describes method to detect motor bearing damage based on wavelet transform since it “has been shown to be an effective tool for the analysis of both transient and steady state power system signals”.

Since the Fourier-based techniques are historically by far the most popular engineering methods to analyze characteristics of data, a need still exists in the art for an improved method, which would provide features of MRA being backward compatible with classical FT approach.

### SUMMARY OF THE PRESENT INVENTION

One aspect of the present invention is to provide method of spectral analysis, backward compatible (both methodically and computationally) with traditional Fourier-based techniques, but free from limitation of static time-frequency resolution, which is often a cause of measurement inaccuracy. It is intended to combine convenience of Fourier-based techniques with advantages of wavelet-based MRA.

This invention provides a novel technique to generalize Fourier-based spectral analysis to the case of adaptive resolution. The proposed generalized transform provides better accuracy of measuring both, frequencies present in data spectrum and timing intervals during which these frequencies are present. Spectral analysis based on this transform can reach fundamental limit implied by the Uncertainty Principle for a set of time-frequency resolutions rather than for a fixed predefined value.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1 is a diagram for showing the 256 samples of simulated signal comprised from three concurrent continuous frequencies with close values around 0.25 (normalized by sampling frequency).

FIG. 2 presents three spectra with different resolutions obtained from sampling sequence in FIG. 3: initial spectrum calculated from 32 samples with redundancy factor 8 (dashed curve) and two iterations enhancing previous frequency resolution by factor 2 (dotted and solid curves respectively). The iterative process gradually resolves all three frequencies comprising original signal in FIG. 3.

FIG. 3 demonstrates spectrogram obtained from a simulated composite signal by using formula in Equation 1 includes two short pulses with good timing localization and three continuous tones which frequencies cannot be precisely determined here due to the Uncertainty Principle.

FIG. 4 demonstrates spectrogram corresponding to maximal frequency resolution f(k, 512, 1) obtained from spectral data presented in FIG. 3 by using formula in Equation 2.

FIG. 5 is spectral representation of real-valued monochromatic signal with frequency k₀=8 and redundancy factor 4 corresponding to 16 data samples. Critical frequency has index 32. This curve is plotted using formula from Equation 8.

### DETAILED DESCRIPTION OF THE PREFERRED EMBODIMENT

The present invention discloses a new and improved method to take a number of initial consecutive spectra with high resolution in time domain (short sequence of samples) and then to improve their frequency resolution by combining two or more consecutive spectra (effectively increasing length of analyzed sampling sequence). Since such operation increases number of resolved frequencies, the initial spectra must provide redundant frequencies allowing later transformation into higher spectral resolutions. Therefore, length of sampling sequence to calculate the initial spectrum determines maximal resolution in time domain whereas redundancy factor-maximal possible improvement of frequency resolution (when consecutive redundant spectra are combined together).

The Equation-1 below provides a formula o obtain the initial spectrum with redundancy factor M from sequence of N samples. The formula is almost identical to FT, except it provides M times more frequencies than the FT. Also, since redundancy is planned to be transformed into higher frequency resolution, M consecutive spectra with same resolution and redundancy factor may be needed. Therefore, the total length of sampling sequence to be analyzed is NM. When M=1, this transform degenerates into classical FT case.

$${f}_{j}^{0} ( k , N , M ) = \frac{1}{N} {\sum }_{t = 0}^{N - 1} f ( t + j N ) W ( kt , NM ) , where \\ W ( X , Y ) = {e}^{\frac{- 2 π i X}{Y}} ; M , N > 0 ; 0 \leq j < M ; 0 \leq k < NM \qquad ( Eq . 1 )$$

In the above formula, the initial spectrums f⁰ with redundancy factor M from sequences of N samples presented by f(t). It is assumed that M consecutive spectra with same resolution and redundancy factor are obtained (denoted by index j). Parameter k represents frequency index.

Equation 2 below presents a formula to transform redundancy into higher frequency resolution by combining two or more consecutive spectra with same resolution characteristics. It can be mathematically proven that such transform may be applied multiple times iteratively until all redundancy is transformed. The ultimate result is a spectrum with maximal frequency resolution, which is equal to FT of the complete sequence of NM samples as shown in Equation 3 later.

$${f}_{p}^{n + 1} ( k , NL , M \vert L ) = \frac{1}{L} {\sum }_{j = 0}^{L - 1} {f}_{j + pL}^{n} ( k , N , M ) W ( kj , M ) ; \\ L > 0 ; 0 \leq p < M \vert L \\ {f}_{j}^{m} ( k , N , M ) = {f}_{j}^{n} ( k , N , M ) = {f}_{j} ( k , N , M ) \qquad ( Eq \text{-} 2 )$$

Specifically, Equation 2 shows how to obtain (n+1)-th iteration of spectrums fⁿ⁺¹ from previous iterations fⁿ by enhancing its frequency resolution by factor L. Note, that this operation also reduces time resolution and redundancy factor by L (so, M must be divisible by L). The result does not depend on number of previous iterations, so iteration index may be omitted.

$$f ( k ) = {f}_{0}^{m} ( k , NM , 1 ) = \frac{1}{NM} {\sum }_{t = 0}^{NM - 1} f ( t ) W ( kt , NM ) ; 0 \leq m \leq {log}_{2} M \qquad ( Eq \text{-} 3 )$$

Equation 3 defines a final iteration (redundancy factor 1) with maximal frequency resolutions f^{m} which is equivalent to Discrete Fourier Transform of the complete sequence of NM samples f(k). Iteration number m reaches maximal value of log₂ M when M is power of 2 and each iteration increases frequency resolution by factor 2.

Depending on how the iterations are done one can obtain plurality of equivalent data representations with different time-frequency resolutions. Each representation can be used individually as classical Fourier spectrum (e.g. for inverse transform to recreate original signal or for any kind of spectral analysis) after redundant frequencies are discarded. Therefore, the set of two transforms defined by formulas in Equation 1 and Equation 2 provide capability of MRA being fully compatible with Fourier methodology.

Equation 4 below shows inverse transform of spectrum with redundancy factor 1, which is equivalent to Inverse Discrete Fourier Transform of the complete sequence of NM samples.

$$\begin{matrix}f ( t ) = {\sum }_{k = 0}^{NM - 1} {f}_{0} ( k , NM , 1 ) W ( - kt , NM ) \\ = {\sum }_{k = 0}^{NM - 1} f ( k ) W ( - kt , NM ) ; 0 \leq t < NM\end{matrix} \qquad ( Eq \text{-} 4 )$$

Equation 5 below shows method of discarding redundancy on the example of inverse transform. To use spectrum with redundancy factor M in place of classical Fourier spectrum, only one out of each M consecutive spectral components should be used. Since spectrum with maximal frequency resolution has no redundancy, (redundancy factor M is equal to 1) it can be used as is; its inverse transform is equal to Inverse Discrete Fourier Transform of the complete sequence of NM samples as shown in Equation 5. Specifically, the following formula shows an inverse transform of redundant spectrum (redundancy factor M is greater than 1). Note, that only one out of each M consecutive frequencies are used.

$$f ( t ) = {\sum }_{k = 0}^{N - 1} f ( kM , N , M ) W ( - kMt , N ) ; 0 \leq t < N \qquad ( Eq \text{-} 5 )$$

It is also remarkable that the resolution transforming iterations can be applied to partial set of frequencies, or different frequencies may be independently transformed to different resolutions. The only constraint is if inverse transform is needed then all frequencies involved in it must have same resolution.

Normalization factors and sign in the exponent can be treated in same way as in classical Fourier transform: they can be conventionally moved between forward and reverse transforms. However for joint analysis of multiple resolutions, it is convenient to have normalization factor 1/L multiplying the resolution transform (Equation 2), so that inverse transform for all resolutions has same normalization and results of all resolution iterations can be directly compared to each other. If results of different measurements with different initial resolutions need to be compared then it may be convenient to place normalization factor 1/N in front of forward transform (Equation 1).

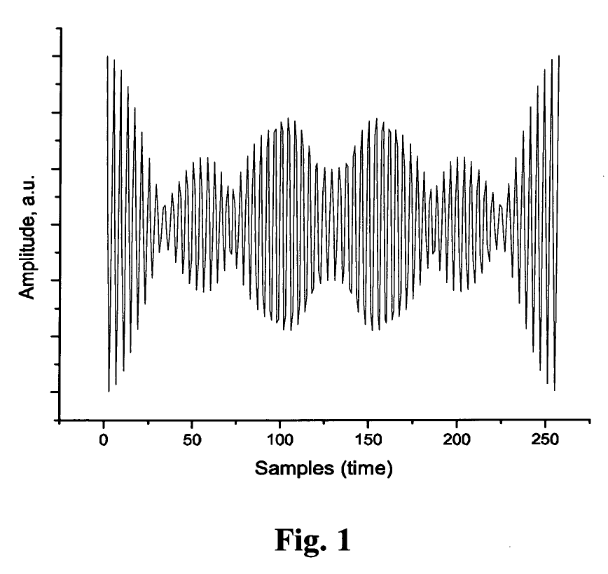

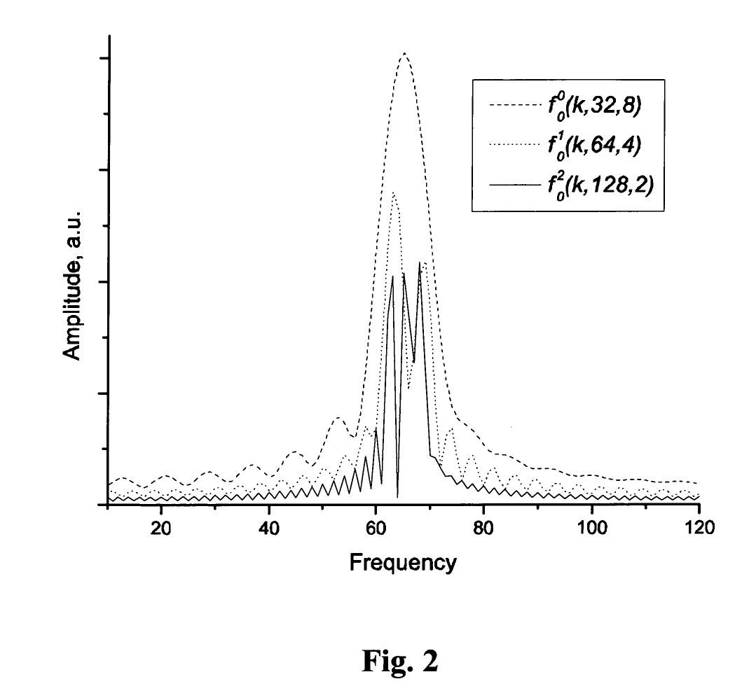

FIG. 2 demonstrates how close frequencies can be gradually resolved in real time by adjustment of time-frequency resolution in spectral analyzer. The analyzed data is a simulated signal comprised from three close frequencies (FIG. 1). Dashed curve in FIG. 2 is initial spectrums f(k, 32, 8) calculated over sequence of first 32 samples with redundancy factor M=8. This spectrum cannot resolve individual contributing frequencies due to the Uncertainty Principle. However after receiving next 32 samples, frequency resolution can be doubled by combining information from two consecutive spectra with M=8 (dotted curve), so that second peak is resolved. Finally, the third spectrum f(k, 128, 2), which resolves all three peaks, is obtained after next 64 samples are received and two consecutive spectra f(k, 64, 4) are combined.

Example of application, which can benefit from gradual improvement of frequency resolution, could be Doppler measurement. Due to the Uncertainty Principle, more precise determination of Doppler shift requires longer sampling sequences to be analyzed. However, if the Doppler shift drifts over time (Doppler drift) better resolution in frequency domain may not end up with higher precision, since over time of the measurement the amount of drift may exceed the intended accuracy. Thus, if the Doppler drift rate is high enough increasing the spectral resolution can in fact deteriorate the measurement precision. Since this rate may not be known in advance it is clear that the optimal time-frequency resolution should be determined in process of measurement as a trade-off between the spectral resolution and the amount of Doppler drift. The same is true for phase-shift measurement since it provides just an alternative way to present spectral data to operator.

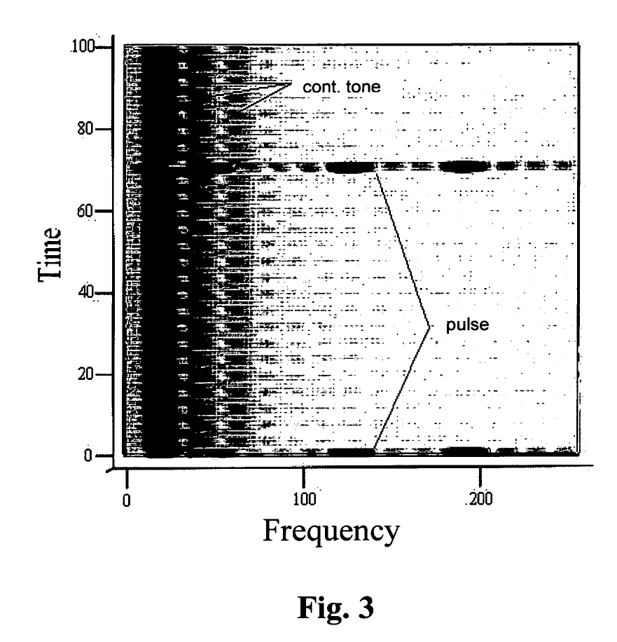

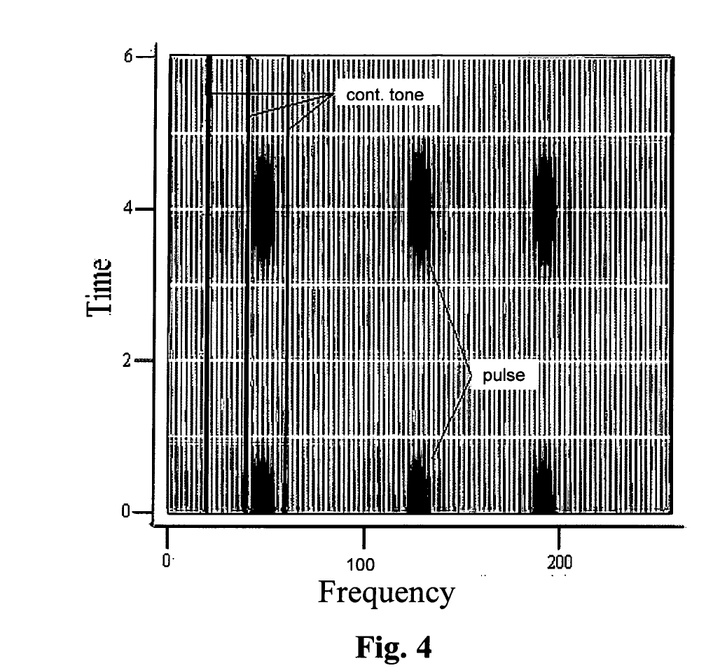

The examples of applications as shown in FIG. 3 and FIG. 4 demonstrate more sophisticated scenario of analyzing composite signal containing both short pulses and continuous tones. In Fourier-based analysis with static time-frequency resolution, precise timing of the pulses and precise frequencies of the continuous tones cannot be measured jointly. It can only be done by MRA technique, which was not available for classical spectral approach prior to this invention. Such measurement can be done in two steps by using the formulas in Equations 1 and 2 respectively. Before using these formulas one needs to decide what should be maximal resolutions in time and frequency domains. The former determines parameter N in Equation 1 (length of sampling sequence for initial spectra; it is assumed that sufficient sampling rate is technically feasible) and the latter—parameter M (redundancy factor; may be limited by performance of the analyzer). As a first step, a set of consecutive initial spectra with maximal resolution in time domain is obtained (FIG. 3). These spectra provide required timing characteristics of the analyzed signal. The second step is transformation of the redundancy into higher frequency resolution after sufficient number of initial spectra is collected (FIG. 4). One can see that joint analysis of the results of the two described steps provides accurate information about both timing of the pulses and frequencies of the continuous tones. When needed, the transformation of resolution may be gradual, generating in a single measurement a plurality of jointly analyzable data representations with different time-frequency resolutions.

Such analysis can be used e.g. in implementing efficient filtering technique. Let's assume that the above signal is unwanted noise added to speech. In order to filter out short pulses (which are characterized by wide spectrum due to the Uncertainty Principle) with minimal side effects, spectral transform with high resolution in time domain should be used. However, spectrum obtained by such transform has poor resolution in frequency domain. Therefore, attempt to filter out continuous tones at this resolution may result in tonality distortions, since significant bandwidth will be affected by such filtering due to poor frequency selectivity (FIG. 3). On the other hand, spectrum with high frequency resolution (which is perfect for filtering out continuous tones) may be suboptimal for filtering out short pulses. Attempt to filter out short pulses at high frequency resolution may result in clipping, since short pulses typically cover significant bandwidth (which may need to be removed) and every spectrum at such resolution translates into longer durations (FIG. 4). Thus, static time-frequency resolution may be inconvenient when filtering out concurrent noises of different origin. Better solution for this problem can be implemented by using the proposed resolution transforming method when short pulses are filtered from spectra providing higher localization in time domain (before redundancy transformation) and the continuous tones—from transformed spectra with higher localization in frequency domain.

Inverse principle works in signal synthesis: components with higher localization in time domain are included into synthesized redundant initial spectra. Then, after redundancy of the initial spectra is transformed into higher frequency resolution, components with higher localization in frequency domain are added. After that, the final spectrum containing all components is inverse Fourier transformed to provide required composite signal in time domain. This approach alone can be used to synthesize data exhibiting spectral features of various resolutions (i.e. speech or music) and together with MRA it can provide efficient infrastructure for active noise suppression.

Equation 6 below shows formula providing spectral representation of monochromatic signal with frequency k₀ and redundancy factor M obtained from sequence of N samples of complex-valued data. Parameter k represents frequency index.

$$\begin{matrix}f ( {k}_{0} , N , M ) = \frac{1}{N} {\sum }_{t = 0}^{N - 1} W ( - {k}_{0} t , NM ) W ( kt , NM ) \\ = \frac{1}{N} {\sum }_{t = 0}^{N - 1} W ( ( k - {k}_{0} ) t , NM ) ; 0 \leq k , {k}_{0} < NM\end{matrix} \qquad ( Eq \text{-} 6 )$$

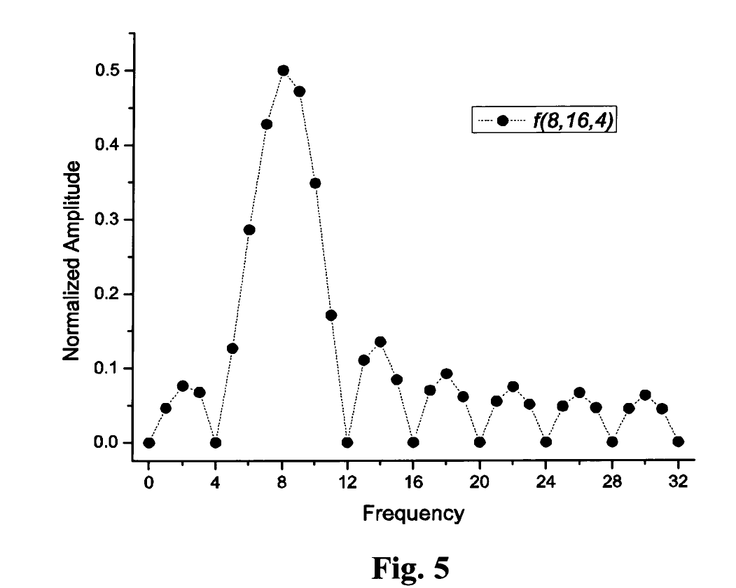

When discussing principles of synthesis, it is important to note that monochromatic signal has nontrivial representation in redundant spectrum. Such spectrum demonstrates periodic fringes covering all frequencies, which result from timing localization of the data (FIG. 5). Analytical representation of complex-valued monochromatic signal is given in Equation 6. If the monochromatic signal is real-valued, calculation of its spectrum can be optimized since spectrum of real-valued data is symmetric: as in classical Fourier Transform, it contains pairs of frequencies which are complex conjugates of each other According to Equation 7 below.

$$\begin{matrix}f ( {k}_{0} , N , M ) = \frac{1}{N} {\sum }_{t = 0}^{N - 1} [ \frac{1}{2} W ( - {k}_{0} t , NM ) + \frac{1}{2} W ( {k}_{0} t , NM ) ] \\ W ( kt , NM ) \\ = \frac{1}{N} {\sum }_{t = 0}^{N - 1} cos ( \frac{2 π {k}_{0} t}{NM} ) W ( kt , NM ) ;\end{matrix} \\ 0 < {k}_{0} < \frac{NM}{2} , 0 \leq k \leq NM \\ \begin{matrix}f ( {k}_{crit} , N , M ) = \frac{1}{N} {\sum }_{t = 0}^{N - 1} W ( - \frac{NM}{2} t , NM ) W ( kt , NM ) \\ = \frac{1}{N} {\sum }_{t = 0}^{N - 1} {e}^{π i t} W ( kt , NM ) \\ = \frac{1}{N} {\sum }_{t = 0}^{N - 1} {( - 1 )}^{t} W ( kt , NM ) ;\end{matrix} \\ if NM is even \\ \begin{matrix}f ( 0 , N , M ) = \frac{1}{N} {\sum }_{t = 0}^{N - 1} W ( 0 t , NM ) W ( kt , NM ) \\ = \frac{1}{N} {\sum }_{t = 0}^{N - 1} W ( kt , NM )\end{matrix} \qquad ( Eq \text{-} 7 )$$

The Equation 7 above shows formula providing spectral representation of real-valued monochromatic signal with frequency k₀ and redundancy factor M obtained from sequence of N samples. As in classical Fourier Transform, second half of spectrum of real-valued data (NM/2<k<NM) is symmetric. Therefore it is possible to present only half of such spectrum limited by critical frequency NM/2. If the critical frequency k_{crit} exists (NM is divisible by 2) then its spectral representation is given by formula f(k_{crit}, N, M). For frequency with index 0 (“DC” component) corresponding representation is f(0, N, M).

The Equation 8 below demonstrates how formula in Equation 1 may be optimized for computation. One can rearrange its NM frequencies into M interleaved sets by substitution of variable k with k′ so that k=k′M+m. It becomes clear now that as a result of this variable substitution (1A) is decomposed into M separate interleaved Fourier transforms of redefined sequence f m(t).

$$\begin{matrix}{f}_{j} ( k , N , M ) = \frac{1}{N} {\sum }_{t = 0}^{N - 1} f ( t + jN ) W ( kt , NM ) \\ = \frac{1}{N} {\sum }_{t = 0}^{N - 1} f ( t + jN ) W ( ( {k}^{′} M + m ) t , NM ) = \\ = \frac{1}{N} {\sum }_{t = 0}^{N - 1} ( f ( t + jN ) W ( mt , NM ) ) W ( {k}^{′} t , N ) \\ = \frac{1}{N} {\sum }_{t = 0}^{N - 1} {f}^{m} ( t + jN ) W ( {k}^{′} t , N ) ,\end{matrix} \\ where {f}^{m} ( t + jN ) = f ( t + jN ) W ( mt , NM ) ; \\ j = 0 … M - 1 ; k = 0 … NM - 1 ; \\ k = {k}^{′} M + m ; m = 0 … M - 1 ; {k}^{′} = 0 … N - 1 \qquad ( Eq \text{-} 8 )$$

Specifically, in order to optimize formula in Equation 1 for computation it may be convenient to rearrange its NM frequencies into M interleaved sets. It can be easily done by variable substitution shown in Equation 8 above. One can see that as a result of this variable substitution the original formula is now decomposed into M separate transforms that can be calculated using standard FFT technique. The frequencies obtained from these transforms must be interleaved as demonstrated in Equation 9 below.

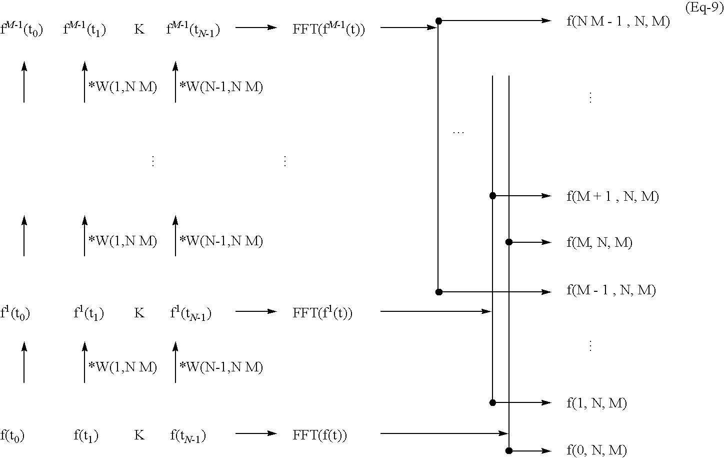

Equation 9 presents the schema for decomposition of Redundant Spectral Transform with redundancy factor M into M interleaved Fourier Transforms.

Other examples of applications of the methods disclosed in this invention may include real time monitoring and diagnostics, speech recognition, identification, image and audio compression.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A method to generalize Fourier-based spectral analysis to the case of adaptive resolution comprising:
applying a generalized transform for providing an improved accuracy of measuring both, frequencies present in data spectrum and timing intervals wherein these frequencies are present; and
applying the spectral analysis based on the transform to reach fundamental limit implied by the Uncertainty Principle for a set of time-frequency resolutions rather than for a fixed predefined value.
